(19) United States
(12) Patent Application Publication
(10) Pub. No.: US 2025/0228144 A1
(43) Pub. Date: Jul. 10, 2025

(54) FORMATION METHOD OF MEMORY CELL

(71) Applicants: TAIWAN SEMICONDUCTOR MANUFACTURING COMPANY, LTD., Hsinchu (TW); NATIONAL TAIWAN UNIVERSITY, Taipei (TW)

(72) Inventors: Jia-Yang LEE, Tainan City (TW); Min-Hung LEE, Taipei City (TW)

(73) Assignees: TAIWAN SEMICONDUCTOR MANUFACTURING COMPANY, LTD., Hsinchu (TW); NATIONAL TAIWAN UNIVERSITY, Taipei (TW)

(21) Appl. No.: 18/404,718

(22) Filed: Jan. 4, 2024

(51) Int. Cl. H10N 70/20; H10B 63/00; H10N 70/00

(52) U.S. Cl. CPC H10N 70/25; H10B 63/80; H10N 70/041

(57) ABSTRACT

A method of forming a memory cell comprises the following steps. A bottom electrode layer is formed over a substrate. A variable resistance film is formed over the bottom electrode layer. The variable resistance film comprises a first orthorhombic phase with a first fraction in the variable resistance film. A top electrode layer is formed over the variable resistance film. A laser anneal process is performed to the substrate, the bottom electrode layer, the variable resistance film and the top electrode layer. After performing the laser anneal process, the variable resistance film comprises a second orthorhombic phase with a second fraction in the variable resistance film, and the second fraction is different from the first fraction.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs and, for these advancements to be realized, similar developments in IC processing and manufacturing are needed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2A, 2B, 2C, 2D, 2E, 3 and 4 illustrate schematic cross-sectional views of a memory cell at various stages of fabrication in accordance with some embodiments of the present disclosure.

FIG. 5A is a laser generating system in accordance with some embodiments.

FIGS. 5B and 5C show polarization-voltage (P-V) characteristic with regard to the memory cell in FIG. 4 after being irradiated using the laser anneal process in accordance with some embodiments.

FIG. 6 shows a simulation result of temperature when the capacitor is irradiated by the laser anneal process in accordance with some embodiments.

FIG. 7A shows polarization-voltage (P-V) characteristic with regard to the memory cell in FIG. 4 at different states in accordance with some embodiments.

FIG. 7B shows capacitance-voltage (C-V) characteristic and relative permittivity-voltage characteristic with regard to the memory cell in FIG. 4 in accordance with some embodiments.

FIGS. 8A, 8B and 8C show capacitors with the corresponding variable resistance film at the pristine state, during being irradiated by the laser anneal process, and after being irradiated by the laser anneal process in accordance with some embodiments.

FIG. 9A shows phases of the variable resistance film at the pristine state.

FIG. 9B shows phases of the variable resistance film after being irradiated by the laser anneal process.

FIG. 9C is an exemplary table indicating phase fractions of memory cell in FIGS. 9A and 9B in accordance with some embodiments.

FIG. 10A is a diagram illustrating switching polarizations (2Pᵣ) versus endurance (cycles) with regard to the capacitor of the memory cell in FIG. 4 in accordance with some embodiments.

FIGS. 10B, 10C and 10D show polarizations (2Pᵣ) versus voltage of the capacitor of the memory cell at the pristine state, cycling using the electric field, woken up using the laser anneal process at the pulse energy of about 140±10 mJ/cm², respectively.

FIG. 11 is an exemplary table indicating waking up the capacitor of the memory cell using a method of an example in accordance with some embodiments and waking up the capacitor of the memory cell using other methods of comparative examples.

FIGS. 12 and 13 illustrate schematic cross-sectional views of a memory cell at various stages of fabrication in accordance with some embodiments of the present disclosure.

FIG. 14 is a semiconductor device including the memory cell according to some embodiments of the present disclosure.

FIG. 15 is a schematic cross-sectional view of an integrated circuit device having memory cells in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may mean within 20 percent, or within 10 percent, or within 5 percent of a given value or range. Numerical quantities given herein are approximate, meaning that the term “around,” “about,” “approximately,” or “substantially” can be inferred if not expressly stated.

Switching current-electric field curves of ferroelectric thin films may show three different stages including pristine, woken-up and fatigued of field cycling. Redistribution of oxygen vacancies assists phase transition in the ferroelectric film. Wake-up effect is related to a displacement of the oxygen vacancies form an interface to a bulk of the ferroelectric film. At the pristine state, the oxygen vacancies are in the interface. Dipole is pinned and is restricted to flip. After the dipole is woken up, oxygen vacancies may move to the bulk of the ferroelectric film. The dipole is free to flip such that switching domains increase. At the fatigued state, the oxygen vacancies generate at the interface. Therefore, the dipole is pinned again, and non-switching domains increase.

However, using an electric field to wake up the dipole has poor throughput characteristic and is incompatible for back end of line (BEOL). In particular, using electric filed to wake up spends extra time for inducing a remnant polarization (Pᵣ).

The present disclosure provides a method to wake up a pristine ferroelectric capacitor to its available state using a laser anneal process, such as a nanosecond laser anneal process to develop a high density ferroelectric Random-access memory (RAM). Nanosecond laser anneal process enables a high throughput process and low thermal budget, and thus is compatible for BEOL. Cost of fabrication process thereof can be reduced.

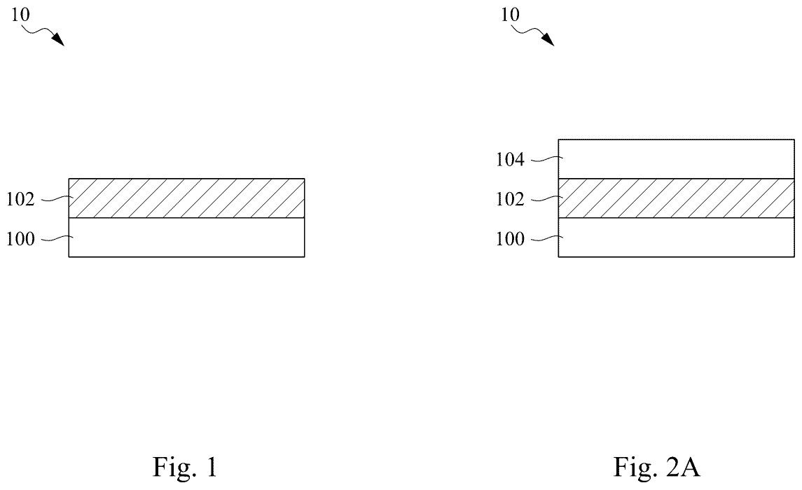

FIGS. 1, 2A, 2B, 2C, 2D, 2E, 3, 4, 12 and 13 illustrate schematic cross-sectional views of a memory cell 10 at various stages of fabrication in accordance with some embodiments of the present disclosure. Reference is made to FIG. 1. A substrate 100 is provided. The substrate 100 may include transistors and one or more interconnect layers formed thereon. The substrate 100 may be a semiconductor substrate, such as silicon substrate. Alternatively, the substrate 100 may include another elementary semiconductor, such as germanium; a compound semiconductor including silicon carbide; an alloy semiconductor including silicon germanium; or combinations thereof. The substrate 100 may include group-IV semiconductor materials, III-V compound semiconductor materials, transition-metal dichalcogenides (TMD). In some embodiments, the substrate 100 is a semiconductor on insulator (SOI) substrate. The substrate 100 may include doped regions, such as p-wells and n-wells. The transistors are formed by suitable transistor fabrication processes and may be a planar transistor, such as polysilicon gate transistors or high-k metal gate transistors, or a multi-gate transistor, such as fin field effect transistors. After the transistors are formed, one or more interconnect layers of a multi-level interconnect (MLI) is formed over the transistors.

A bottom electrode layer 102 is deposited over the substrate 100. In some embodiments, the bottom electrode layer 102 may include suitable conductive materials, such as TaN, TiN, W, Pt, Mo, Ta, Ti, metal silicide, the like, or a combination thereof. The bottom electrode layer 102 can be a single-layered structure or a multi-layered structure including plural stacked layers of metals and/or metal-containing compounds. The bottom electrode layer 102 may be exemplarily formed by chemical vapor deposition (CVD), physical vapor deposition (PVD) (e.g., sputtering deposition), atomic layer deposition (ALD), the like, and/or the combination thereof. In some embodiments, a thickness of the bottom electrode layer 102 may be in a range from about 1 nanometer to about 1000 nanometers. In some other embodiments, the bottom electrode layer 102 may have other suitable thickness. In some embodiments, the bottom electrode layer 102 may have a thickness in a range from about 1 nm to about 5 nm, such as about 2 nm.

Reference is made to FIG. 2A. A variable resistance film 104 is deposited over the bottom electrode layer 102. In some embodiments, the variable resistance film 104 is a hafnium-containing film. In some embodiments, the variable resistance film 104 may include HfO₂, HfZrO₂ (HZO), aluminum-doped HfO₂ (HAO), silicon-doped HfO₂ (HSO), lead zirconate titanate (PZT), strontium bismuth tantalite (SBT), the like, or a combination thereof. In some embodiments, the variable resistance film 104 has a thickness in a range from about 0.1 nm to about 50 nm. In some embodiments, the variable resistance film 104 has a tetragonal phase, an orthorhombic phase or a combination thereof. In some embodiments, the variable resistance film 104 is ferroelectric or antiferroelectric. In some embodiments, the variable resistance film 104 is formed by ALD or PVD.

Reference is made to FIG. 2B. In some embodiments, the variable resistance film 104 is a multilayer stack including a dielectric film 106 and a ferroelectric film 108 over the dielectric film 106. Reference is made to FIG. 2C. In some other embodiments, the variable resistance film 104 is a multilayer stack including a dielectric film 106 and an antiferroelectric film 110 over the dielectric film 106. Reference is made to FIG. 2D. In some embodiments, the variable resistance film 104 is a multilayer stack including a ferroelectric film 108 and a dielectric film 106 over the ferroelectric film 108. Reference is made to FIG. 2E. In some other embodiments, the variable resistance film 104 is a multilayer stack including an antiferroelectric film 110 and a dielectric film 106 over the antiferroelectric film 110. The dielectric film 106 in FIGS. 2B-2E may have a thickness in a range from about 0.1 nm to about 10 nm, and may include SiO₂, Al₂O₃, HfO₂, ZrO₂, or a combination thereof.

Reference is made to FIG. 3. A top electrode layer 112 is deposited over the variable resistance film 104. In some embodiments, the top electrode layer 112 may include suitable conductive materials, such as TaN, TiN, W, Pt, Mo, Ta, Ti, metal silicide, the like, or a combination thereof. The top electrode layer 112 can be a single-layered structure or a multi-layered structure including plural stacked layers of metals and/or metal-containing compounds. The top electrode layer 112 may be exemplarily formed by CVD, PVD (e.g., sputtering deposition), ALD, the like, and/or the combination thereof. In some embodiments, a thickness of the top electrode layer 112 may be in a range from about 1 nanometer to about 1000 nanometers. In some other embodiments, the top electrode layer 112 may have other suitable thickness. The top electrode layer 112 may include a conductive material the same as or different from that of the bottom electrode layer 102. The bottom electrode layer 102, the variable resistance film 104 and the top electrode layer 112 constitute a capacitor 114 for storing memory data.

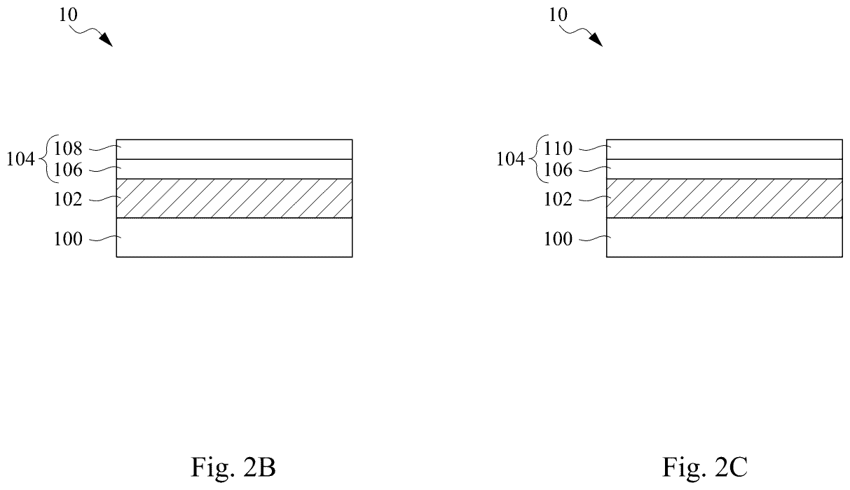

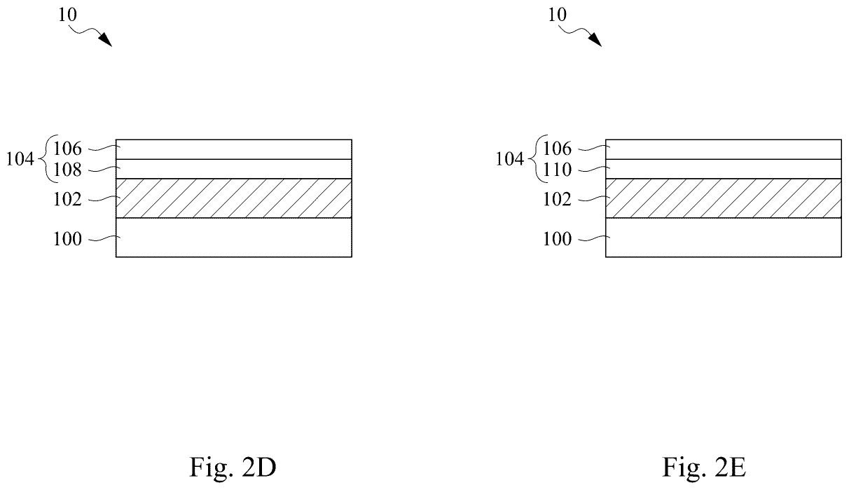

FIG. 5A is a laser generating system 200 in accordance with some embodiments. Reference is made to FIGS. 4 and 5A. The memory cell 10 may be formed as part of a wafer 12. A laser anneal process S100 is performed to the memory cell 10 using the laser generating system 200 in some embodiments. In some embodiments, the laser generating system 200 includes a laser source 202, reflect mirrors 204a, 204b, 204c, a filter 206 and convex lens 208. The laser source 202 may be a solid state laser source such as an Nd: YAG laser, and is used to generate a laser beam 210 having a pulse duration of about 1 nanoseconds (ns) to about 30 nanoseconds, such as about 10 ns, and a pulse energy of about 100 mJ to about 200 mJ, such as about 140 mJ. That is, the laser anneal process can be referred to as a nanosecond laser anneal process. The pulse duration (pulse width) is the time measured across a pulse at its full width half maximum (FWHM). The wavelength of the laser beam 210 is about 300 nm to about 400 nm, such as about 355 nm. In some embodiments, the laser anneal process $100 performed to the memory cell 10 includes a plurality of laser shots. The plurality of laser shots is performed using the laser beam 210 generated by the laser source 202. In each of the laser shots, the laser beam 210 generated by the laser source 202 is projected to the reflect mirrors 204a, 204b, passes through the filter 206, is projected to the reflect mirror 204c, and passes through the convex lens 208, and then is projected on a top surface of the top electrode layer 112 of the memory cell 10, so that heat is absorbed by the top electrode layer 112 and conducted through the variable resistance film 104 to the bottom electrode layer 102 and the substrate 100, causing the wake-up of the variable resistance film 104.

In some embodiments, the laser anneal process S100 may be performed using the laser beam 210 having the wavelength in a range from about 150 nm to about 1064 nm. FIGS. 5B and 5C show polarization-voltage (P-V) characteristic with regard to the memory cell 10 in FIG. 4 after being irradiated using the laser anneal process S100 in accordance with some embodiments. In FIG. 5B, the laser anneal process S100 performed to the memory cell 10 uses the laser beam 210 with a wavelength in a range from about 300 nm to about 400 nm, such as about 355 nm. In FIG. 5C, the laser anneal process S100 performed to the memory cell 10 uses a laser beam 210 with a wavelength in a range from about 1000 nm to about 1100 nm, such as about 1064 nm. The P-V characteristics in FIGS. 5B and 5C both can exhibit a wake-up effect.

An absorption coefficient of the top electrode layer 112 is related to an efficiency of the heat absorbed by the top electrode layer 112, and the wavelength of the laser beam 210 dominates a temperature of the variable resistance film 104 for efficiency of wake up. In some embodiments where the top electrode layer 112 is made of TiN, W, or TaN, laser energy of the laser beam can be effectively absorbed by the TiN, W, or TaN, since TiN, W, or TaN have a high absorption efficiency to the laser beam 210 with a wavelength of less than about 400 nm. When the top electrode layer 112 is irradiated by the laser anneal process, the top electrode layer 112 may have a raised temperature and heat may flux from the top electrode layer 112 to the underneath variable resistance film 104 for phase transition of the variable resistance film 104, which will be discussed in greater detail later.

In some embodiments, the plurality of laser shots is in a range from about 1 to about 10, such as about 2. In some other embodiments, the laser source may be a gas state laser source, a liquid state laser source, or a semiconductor laser source. In some embodiments, the laser anneal process is performed using a laser power in a range from about 2 W to about 200 W. In some embodiments, the laser anneal process is performed using a laser beam having a wavelength of about 150 nm to about 1064 nm. In some embodiments, the laser anneal process is performed using the laser pulse having a pulse duration (or a pulse width) in a range from about 1 ns to about 20 ns, such as about 10 ns.

In some embodiments, the laser anneal process may be performed using the laser beam 210 having a pulse duration in a range from about 1 fs to about 40 ns, and a pulse repetition rate in a range from about 1 Hz to about 200 kHz. In some other embodiments, an additional anneal process may be performed to wake up the variable resistance film 104, such as rapid thermal annealing (RTA), laser spike annealing (LSA), furnace annealing, microwave annealing, or flash annealing.

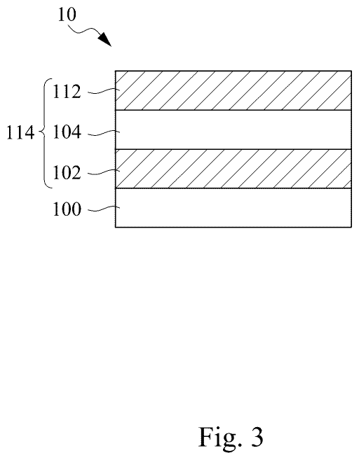

FIG. 6 shows a simulation result of temperature when the capacitor 114 is irradiated by the laser anneal process in accordance with some embodiments. Reference is made to FIGS. 4 and 6. In some embodiments where the capacitor 114 is irradiated using a nanosecond laser anneal process to generate a laser beam having a pulse duration of about 1 nanoseconds (ns) to about 30 nanoseconds, a pulse energy of about 100 mJ to about 200 mJ, such as about 140 mJ, the variable resistance film 104 has an increased temperature in a range from about 600° C. to about 800° C., such as about 700° C., and the substrate 100 may have an increased temperature in a range from about 300° C. to about 500° C., such as about 400° C. The increased temperature of the substrate 100 is not too high. Therefore, wake up a pristine capacitor 114 to its available state using such nanosecond laser anneal process can enable a high throughput process and low thermal budget, and thus is compatible for BEOL. Cost of fabrication process thereof can be reduced. A high density ferroelectric random-access memory (RAM) can thus be developed. In some embodiments, the laser anneal process, such as the nanosecond laser anneal process, can be used to wake up a ferroelectric RAM (FeRAM), a dynamic RAM (DRAM), a static RAM (SRAM), or an NAND flash memory.

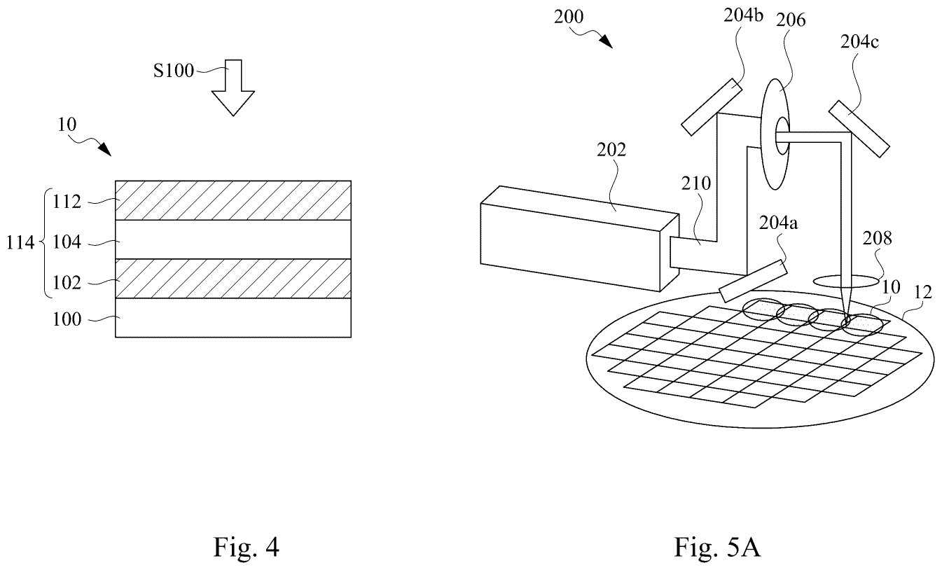

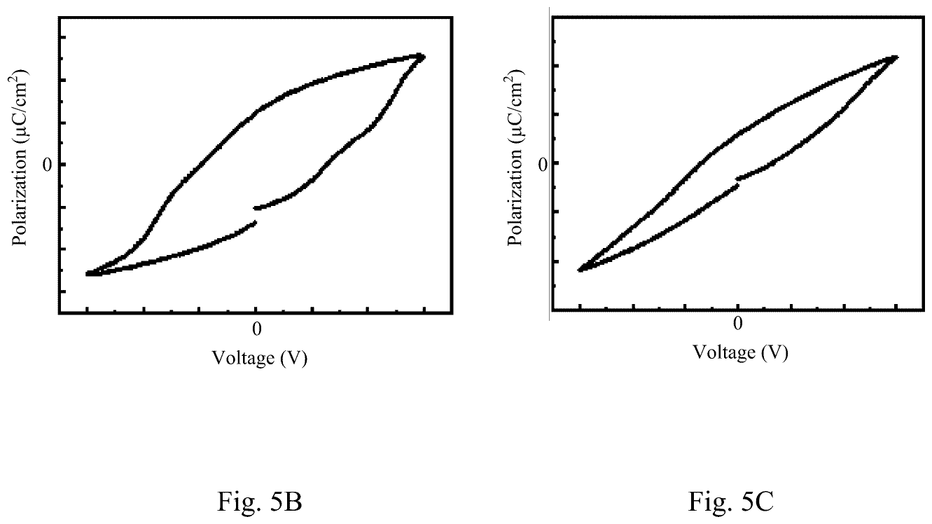

FIG. 7A shows polarization-voltage (P-V) characteristic with regard to the memory cell 10 in FIG. 4 at different states in accordance with some embodiments. Reference is made to FIG. 7A. A curve 1000 shows the variable resistance film 104 at a pristine state. A curve 1002 and a curve 1004 show the variable resistance film 104 irradiated by the laser anneal process to wake up the variable resistance film 104 and cycling by an electric field, respectively. The variable resistance film 104 at the pristine state exhibits an antiferroelectric like behavior. The variable resistance film 104 irradiated by laser anneal process and cycling by the electric field both exhibit a ferroelectric behavior, indicating that the laser anneal process can assist in waking up the variable resistance film 104 and increasing a fraction of orthorhombic phase in the variable resistance film 104. In other words, the laser anneal process is performed such that the variable resistance film 104 undergoes a crystal phase transformation and an antiferroelectric to ferroelectric transformation.

FIG. 7B shows capacitance-voltage (C-V) characteristic and relative permittivity-voltage characteristic with regard to the memory cell 10 in FIG. 4 in accordance with some embodiments. Reference is made to FIG. 7B. A curve 1006 shows the variable resistance film 104 at a pristine state. A curve 1008 and a curve 1010 show the variable resistance film 104 irradiated by laser anneal process to wake up the variable resistance film 104 and cycling by the electric field, respectively. It is noted that a relative permittivity of a tetragonal phase (t-phase) is higher than a relative permittivity of an orthorhombic phase (o-phase). In FIG. 7B, the variable resistance film 104 at the pristine state exhibits a relative permittivity higher than a relative permittivity of the variable resistance film 104 irradiated by laser anneal process and a relative permittivity of the variable resistance film 104 cycling by the electric field, indicating that the variable resistance film 104 irradiated by laser anneal process and cycling by the electric field have the o-phase, and the laser anneal process to wake up the variable resistance film 104 can assist in increasing a fraction of the o-phase in the variable resistance film 104.

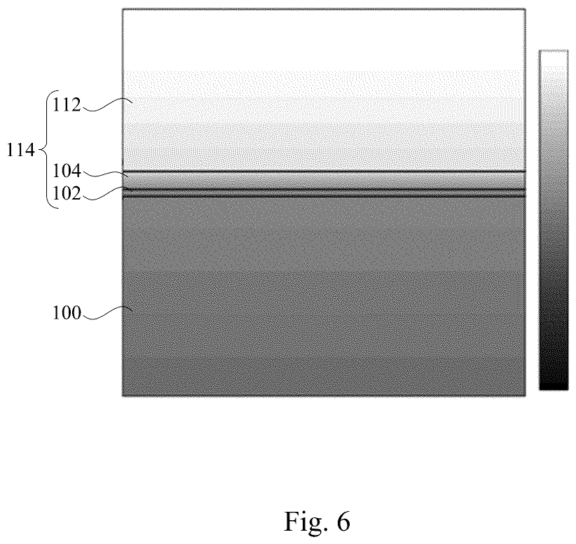

FIGS. 8A, 8B and 8C show the capacitors 114 with the corresponding variable resistance film 104 at the pristine state, during being irradiated by the laser anneal process, and after being irradiated by the laser anneal process in accordance with some embodiments. The substrate 100 of the memory cell 10 is omitted in FIGS. 8A, 8B and 8C. In FIGS. 8A and 8B, a portion of the variable resistance film 104 on the left hand side includes a tetragonal phase, and a portion of the variable resistance film 104 on the right hand side includes an orthorhombic phase. Positions of these portions of the variable resistance film 104 are shown for discussion, and the present disclosure is not limited thereto. At the pristine state, oxygen vacancies 116 are in interfaces, such as an interface between the top electrode layer 112 and the variable resistance film 104, an interface between the bottom electrode layer 102 and the variable resistance film 104, and interfaces between domains 118 in the variable resistance film 104. Dipoles 120 in the domains 118 are pinned by oxygen vacancies 116 which have charge and are restricted to flip in the domains 118 of the variable resistance film 104. The term “dipole,” “dipole moment” or “electrical dipole moment” refers to a measure of the separation of positive and negative electrical charges in a system of charges, that is, a measure of the charge system's overall polarity (with, for example, SI units of Coulomb-meter (Cm)).

Reference is made to FIG. 8B. During being irradiated by the laser anneal process, such as using the nanosecond laser anneal process, the oxygen vacancies 116 may de-pinned the dipoles 120 of the variable resistance film 104 because the dipoles 120 may oscillate caused by a thermal energy provided by the laser anneal process. Therefore, the capacitor 114 can be woken up. Reference is made to FIG. 8C. After the capacitor 114 is irradiated by the laser anneal process, the variable resistance film 104 has a portion becoming an orthorhombic phase. For example, the left hand side of the portion of the variable resistance film 104 becomes the orthorhombic phase.

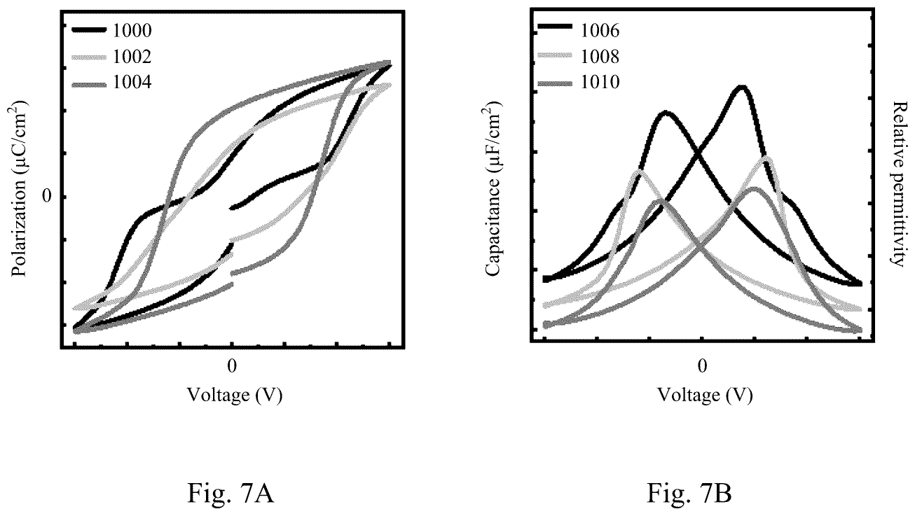

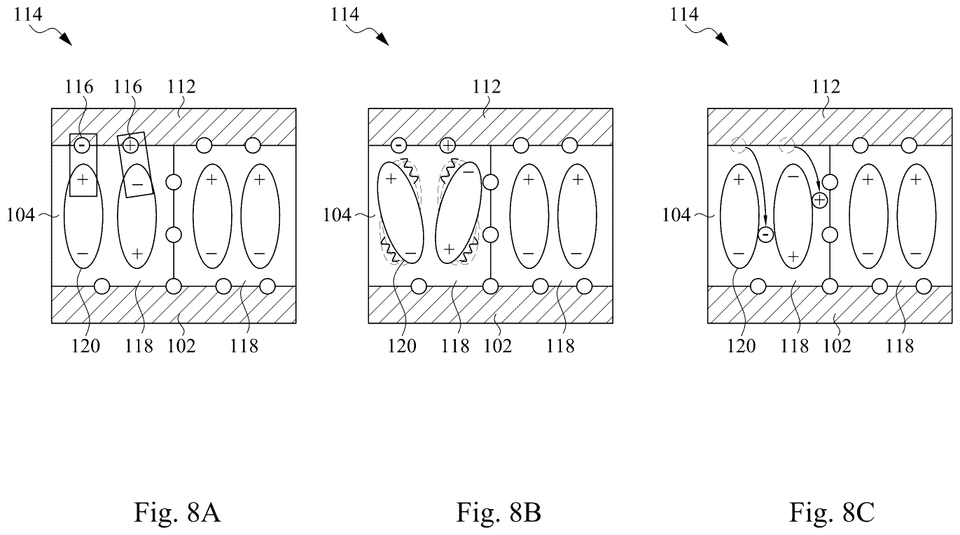

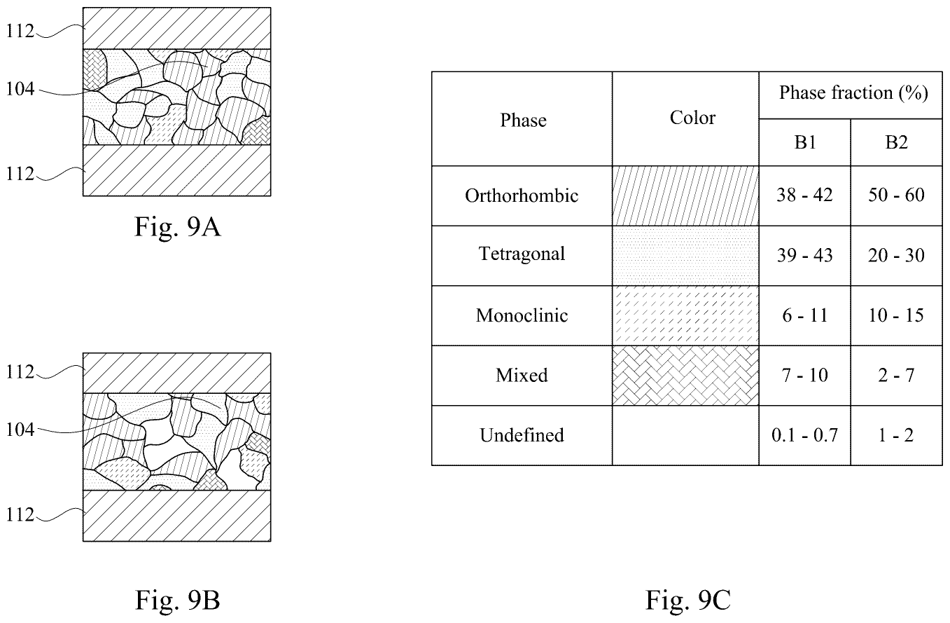

FIG. 9A shows phases of the variable resistance film 104 at the pristine state. FIG. 9B shows phases of the variable resistance film 104 after being irradiated by the laser anneal process. The substrate 100 of the memory cell 10 is omitted in FIGS. 9A and 9B. FIG. 9C is an exemplary table indicating phase fractions of the memory cell 10 in FIGS. 9A and 9B in accordance with some embodiments. Blocks B1 and B2 correspond to the phase fractions of the variable resistance film 104 in FIGS. 9A and 9B, respectively. Reference is made to FIGS. 9A and 9C. The variable resistance film 104 at the pristine state may have a plurality of phases different from one another. For example, the variable resistance film 104 includes an orthorhombic phase, a tetragonal phase, a monoclinic phase, a mixed phase and an undefined phase. Fractions of these phases in the variable resistance film 104 may be different from one another. In some embodiments, the fraction of the orthorhombic phase in the variable resistance film 104 may be more than two times of the fraction of the tetragonal phase in the variable resistance film 104. In some embodiments, the monoclinic phase has a fraction in the variable resistance film 104 less than the fraction of the tetragonal phase in the variable resistance film 104. In some embodiments, the monoclinic phase has the fraction in the variable resistance film 104 less than the fraction of the orthorhombic phase in the variable resistance film 104. In some embodiments, the fraction of the orthorhombic phase in the variable resistance film 104 is greater than 50% of total phases present in the variable resistance film 104. For example, the variable resistance film 104 has the orthorhombic phase with a phase fraction in a range from about 38% to about 42%, such as about 40.4%, the tetragonal phase with a phase fraction in a range from about 39% to about 43%, such as about 41.4%, the monoclinic phase in a range from about 6% to about 11%, such as about 9.3%, the mixed phase in a range from about 7% to about 10%, such as about 8.8%, and the undefined phase in a range from about 0.1% to about 0.7%, such as about 0.4%. In some embodiments, in FIG. 9A, the orthorhombic phase may have the phase fraction less than the phase fraction of the tetragonal phase.

Reference is made to FIGS. 9B-9C. The variable resistance film 104 after being irradiated by the laser anneal process may have a plurality of phases different from one another. For example, the variable resistance film 104 may include an orthorhombic phase, a tetragonal phase, a monoclinic phase, a mixed phase and an undefined phase. Fractions of these phases in the variable resistance film 104 may be different from one another. For example, the variable resistance film 104 has the orthorhombic phase with a phase fraction in a range from about 50% to about 60%, such as about 56.3%, a tetragonal phase with a phase fraction in a range from about 20% to about 30%, such as about 24.3%, a monoclinic phase in a range from about 10% to about 15%, such as about 13.3%, a mixed phase in a range from about 2% to about 7%, such as about 4.5%, and an undefined phase in a range from about 1% to about 2%, such as about 1.6%. In some embodiments, in FIG. 9B, the orthorhombic phase may have the phase fraction greater than the phase fraction of the tetragonal phase. In other words, irradiating the variable resistance film 104 using the laser anneal process can increase the phase fraction of the orthorhombic phase in the variable resistance film 104 and reduce the phase fraction of the tetragonal phase in the variable resistance film 104.

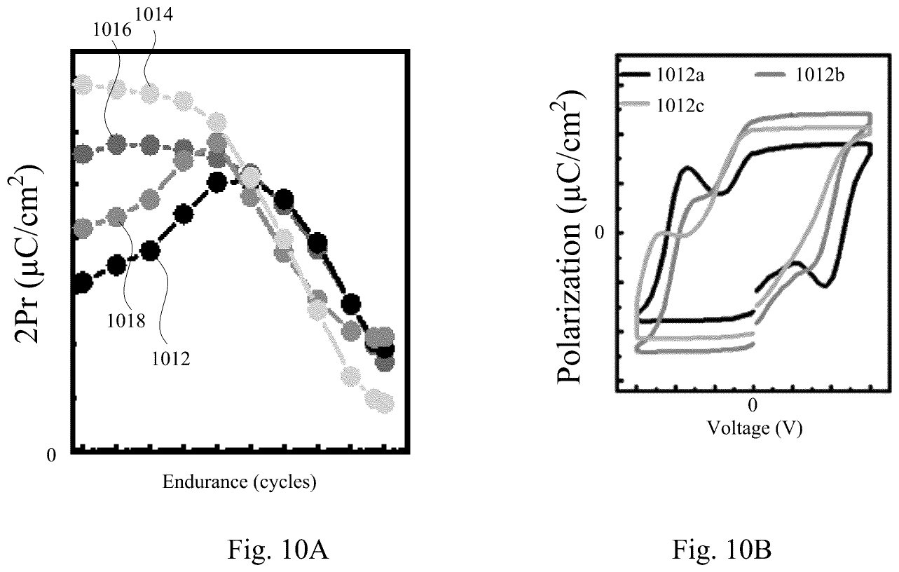

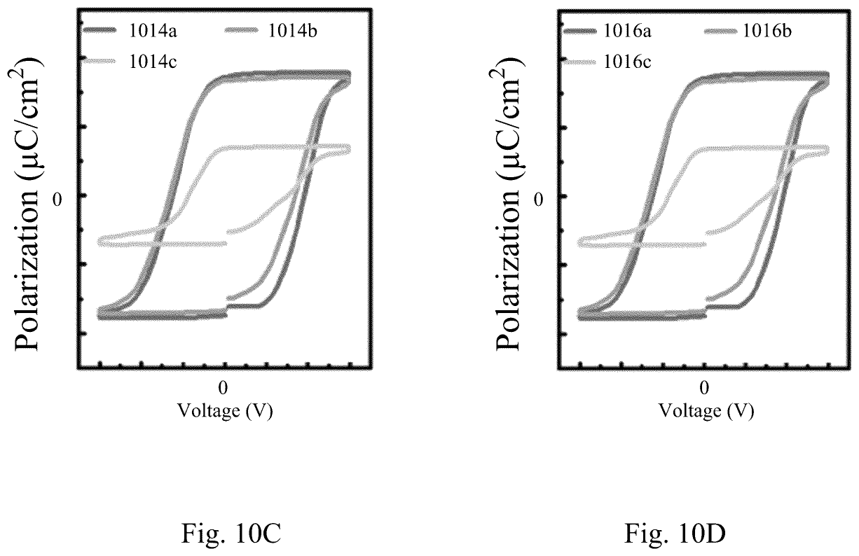

FIG. 10A is a diagram illustrating switching polarizations (2Pᵣ) versus endurance (cycles or switching cycles) with regard to the capacitor 114 of the memory cell 10 in FIG. 4 in accordance with some embodiments. Reference is made to FIGS. 4 and 10A. Curves 1012, 1014, 1016, and 1018 show the switching polarizations of the memory cell 10 at a pristine state, cycling using the electric field, woken up by the laser anneal process at a pulse energy of about 140±10 mJ/cm², and woken up by the laser anneal process at a pulse energy of about 110±10 mJ/cm², respectively. The fatigue of the capacitor 114 of the memory cell 10 is improved by using the laser anneal process at the pulse energy of about 140±10 mJ/cm² at cycles from about 10⁵ to about 10⁹ cycles, as compared to cycling using the electric field.

FIGS. 10B, 10C and 10D show polarizations (2Pᵣ) versus voltage of the capacitor 114 of the memory cell 10 at the pristine state, cycling using the electric field, woken up using the laser anneal process at the pulse energy of about 140±10 mJ/cm², respectively. Reference is made to FIGS. 4 and 10B. Curves 1012a, 1012b, 1012c in FIG. 10B show cycling for about 10⁰ cycle, 10³±100 cycles, and 10⁷±100 cycles, respectively. The capacitor 114 at the pristine state after rapid thermal annealing (RTA) shows that the polarization (2Pᵣ) increases with a cycling number, and means that a wake up effect occurs. Reference is made to FIGS. 4, 10C and 10D. Curves 1014a, 1014b, 1014c in FIG. 10C show cycling for about 10⁰ cycle, 10³±100 cycles, and 10⁷±100 cycles, respectively. Curves 1016a, 1016b, 1016c in FIG. 10D show cycling for about 10⁰ cycle, 10³±100 cycles, and 10⁷±100 cycles, respectively. The capacitor 114 shows almost unchanged polarizations (2Pᵣ) until fatigue for cycling using the electric field and woken up using the laser anneal process.

It indicates that waking up the capacitor 114 of the memory cell 10 using the laser anneal process can increase a fraction of the o-phase in the variable resistance film 104. In other words, a wake-up effect can be improved by the laser anneal process. Stress fatigue caused by cycling using electric field can be avoided as well.

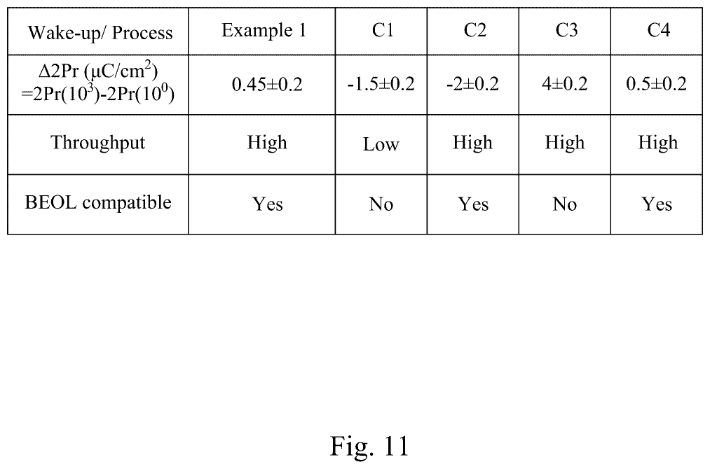

FIG. 11 is an exemplary table indicating waking up the capacitor 114 of the memory cell 10 of FIG. 4 using a method of an example 1 in accordance with some embodiments and waking up the capacitor 114 of the memory cell 10 using other methods of comparative examples C1, C2, C3, and C4. Reference is made to FIGS. 4 and 11. In the comparative example C1, the capacitor 114 is woken up using an electric filed cycling. In the comparative example C2, the variable resistance film 104 is formed by plasma enhanced atomic vapor deposition (PEALD). In the comparative example C3, the top electrode layer and the bottom electrode layer may be optimized by suitable methods. In the comparative example C4, an NH₃ treatment may be performed to the capacitor 114. Reference is made to FIGS. 4 and 11. The capacitor 114 of the memory cell 10 woken up by the laser anneal process shows a variation of switching polarization (Δ2Pᵣ) between a switching polarization (2Pᵣ) at cycling for 10³ cycles and the switching polarization (2Pᵣ) at 10⁰ cycle less than the variations of switching polarization (Δ2Pᵣ) between a switching polarization (2Pᵣ) at cycling for 10³ cycles and the switching polarization (2Pᵣ) at 10⁰ of the comparative examples C1, C2, C3 and C4. As compared to the comparative example C1, the capacitor 114 of the memory cell 10 woken up by the laser anneal process shows a higher throughput and more compatible for back end of line (BEOL).

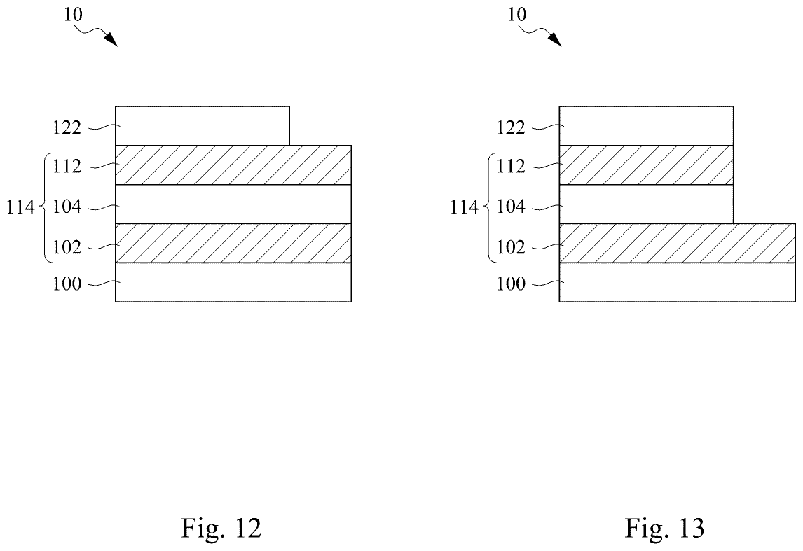

Reference is made to FIG. 12. A resist layer 122 is formed over the top electrode layer 112. In some embodiments, the resist layer 122 is an ashing removable dielectric (ARD), which is a photoresist-like material generally having the properties of a photoresist and amendable to etching and patterning like a photoresist. The resist layer 122 may also acts as a mask layer for patterning underlying layers in some embodiments. The resist layer 122 may be formed by spin-on coating. In some embodiments, an exposure apparatus including a light source and a mask (not shown) is used for providing light for exposing the resist layer 122. The resist layer 122 may be patterned using suitable photolithography process. For example, the photolithography process may include photoresist coating (e.g., spin-on coating), soft baking, mask aligning, exposure, post-exposure baking, developing the photoresist, rinsing, drying (e.g., hard baking), other suitable processes, or combinations thereof.

Reference is made to FIG. 13. One or more etching processes are performed to etch the top electrode layer 112 and the variable resistance film 104 through the patterned resist layer 122, such that portions of the variable resistance film 104 and the top electrode layer 112 uncovered by the patterned resist layer 122 are removed. The one or more etching processes may include a dry etch using fluoride-based etchants. In some other embodiments, the bottom electrode layer 102 may also be patterned through the etching processes.

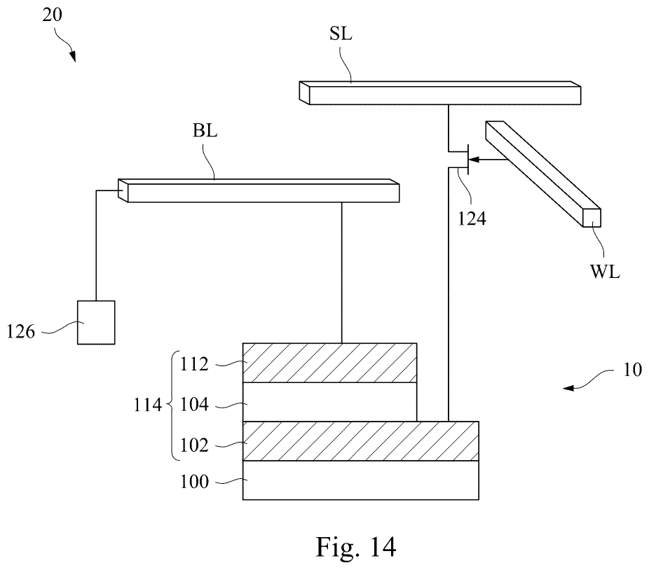

FIG. 14 is a semiconductor device 20 including the memory cell 10 according to some embodiments of the present disclosure. The semiconductor device 20 includes the memory cell 10 including the capacitor 114, an access transistor 124, a conductive line BL that may function as a data line (e.g., a bit line), a conductive line WL that may function as an access line (e.g., a word line), a conductive line SL that may function as a source line, and a periphery device 126 such as a read/write circuitry. To initiate programming of the memory cell 10, the periphery device 126 may generate a programming voltage to the conductive line BL and the conductive line SL. The polarity of the voltage between the conductive line BL and the conductive line SL may determine the polarization direction of the variable resistance film 104 in the capacitor 114. The programmed logic state of the memory cell 10 may be a function of the direction of polarization of the variable resistance film 104 of the capacitor 114. To read the memory cell 10, the periphery device 126 may generate a read voltage to the conductive line BL and the conductive line SL through the capacitor 114 and the access transistor 124. The programmed state of the memory cell 10 may be related to a direction of the polarization of the variable resistance film 104 in the capacitor 114.

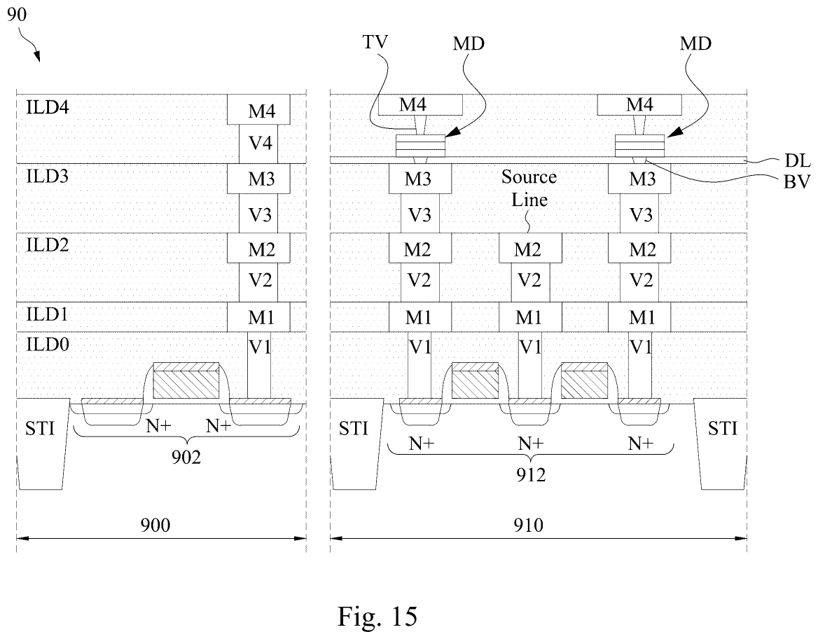

FIG. 15 is a schematic cross-sectional view of an integrated circuit device 90 having memory cells MD in accordance with some embodiments of the present disclosure. The integrated circuit device 90 includes a logic region 900 and a memory region 910. The logic region 900 may include circuitry, such as an exemplary logic transistor 902, for processing information received from the memory cell MD in the memory region 910 and for controlling reading and writing functions of the memory cell MD. In some embodiments, the memory cell MD may be similar to those shown above. In some embodiments, the memory cell MD is located on a bottom electrode via BV connected to underlying metallization layer. The formation of the bottom electrode via BV may include depositing a dielectric layer DL, etching an opening in the dielectric layer DL, and filling the opening with suitable conductive material, followed by a CMP process.

As depicted, the integrated circuit device 90 is fabricated using four metallization layers, labeled as M1 through M4, with four layers of metallization vias or interconnects, labeled as V1 through V4. Other embodiments may contain more or fewer metallization layers and a corresponding more or fewer number of vias. The logic region 900 includes a full metallization stack, including a portion of each of metallization layers M1-M4 connected by interconnects V2-V4, with V1 connecting the stack to a source/drain contact of the logic transistor 902. The memory region 910 includes a full metallization stack connecting the memory cell MD to transistors 912 in the memory region 910, and a partial metallization stack connecting a source line to the transistors 912 in the memory region 910. The memory cells MD are depicted as being fabricated in between the top of the M3 layer and the bottom of the M4 layer. In the illustrated embodiments, a top electrode via TV connects the top electrode TE to the M4 layer, and a bottom electrode via BV connects the bottom electrode BE to the M3 layer. Also included in semiconductor device is a plurality of ILD layers. Five ILD layers, identified as ILD0 through ILD4 are depicted as spanning the logic region 900 and the memory region 910. The ILD layers may provide electrical insulation as well as structural support for the various features of the semiconductor device during many fabrication process steps.

Based on the above discussions, it can be seen that the present disclosure offers advantages. It is understood, however, that other embodiments may offer additional advantages, and not all advantages are necessarily disclosed herein, and that no particular advantage is required for all embodiments. One advantage is that by waking up a pristine capacitor to its available state using a nanosecond laser anneal process, a high density ferroelectric Random-access memory (RAM) can be developed. Another advantage is that the nanosecond laser annealing process enables a high throughput process and low thermal budget, and thus is compatible for BEOL. Another advantage is that cost of fabrication process thereof can be reduced.

In some embodiments, a method of forming a memory cell comprises the following steps. A bottom electrode layer is formed over a substrate. A variable resistance film is formed over the bottom electrode layer. The variable resistance film comprises a first orthorhombic phase with a first fraction in the variable resistance film. A top electrode layer is formed over the variable resistance film. A laser anneal process is performed to the substrate, the bottom electrode layer, the variable resistance film and the top electrode layer. After performing the laser anneal process, the variable resistance film comprises a second orthorhombic phase with a second fraction in the variable resistance film, and the second fraction is different from the first fraction. In some embodiments, the second fraction is higher than the first fraction. In some embodiments, performing the laser anneal process comprises irradiating the top electrode layer using a laser beam having a pulse duration of about 1 nanoseconds to about 30 nanoseconds. In some embodiments, performing the laser anneal process comprises irradiating the top electrode layer using a laser beam having a wavelength in a range from about 300 nm to about 400 nm. In some embodiments, performing the laser anneal process comprises irradiating the top electrode layer using a laser beam having a wavelength in a range from about 1000 nm to about 1100 nm.

In some embodiments, a method of forming a memory cell comprises the following steps. A bottom electrode layer is formed over a substrate. A variable resistance film is formed over the bottom electrode layer. The variable resistance film comprises a first tetragonal phase with a first fraction in the variable resistance film. A top electrode layer is formed over the variable resistance film. A laser anneal process is performed to the bottom electrode layer, the variable resistance film and the top electrode layer, wherein after performing the laser anneal process, the variable resistance film comprises a second tetragonal phase with a second fraction in the variable resistance film, and the second fraction is different from the first fraction. In some embodiments, the second fraction is lower than the first fraction. In some embodiments, prior to performing the laser anneal process, the variable resistance film has an antiferroelectric phase. In some embodiments, after performing the laser anneal process, the variable resistance film has a ferroelectric phase. In some embodiments, after performing the laser anneal process, the variable resistance film has an orthorhombic phase with a third fraction in the variable resistance film, and the third fraction is higher than the first fraction. In some embodiments, after performing the laser anneal process, the variable resistance film has an orthorhombic phase with a third fraction in the variable resistance film, and the third fraction is higher than the second fraction. In some embodiments, performing the laser anneal process comprises irradiating the top electrode layer using a laser beam having a pulse duration of about 1 nanoseconds to about 30 nanoseconds. In some embodiments, the laser beam is generated from a solid state laser source, a liquid state laser source, a gas state laser source or a semiconductor laser source. In some embodiments, the laser beam is generated from a solid state laser source. In some embodiments, the solid state laser source is Nd: YAG.

In some embodiments, a memory cell comprises a substrate, a bottom electrode layer over the substrate, a variable resistance film over the bottom electrode layer and a top electrode layer over the variable resistance film. The variable resistance film comprises a plurality of phases comprising a tetragonal phase and an orthorhombic phase with a fraction in the variable resistance film greater than a fraction of the tetragonal phase in the variable resistance film. In some embodiments, the fraction of the orthorhombic phase in the variable resistance film is more than two times of the fraction of the tetragonal phase in the variable resistance film. In some embodiments, the variable resistance film further comprises a monoclinic phase with a fraction in the variable resistance film less than the fraction of the tetragonal phase in the variable resistance film. In some embodiments, the variable resistance film further comprises a monoclinic phase with a fraction in the variable resistance film less than the fraction of the orthorhombic phase in the variable resistance film. In some embodiments, the fraction of the orthorhombic phase in the variable resistance film is greater than 50% of total phases present in the variable resistance film.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a memory cell, comprising:
forming a bottom electrode layer over a substrate;
forming a variable resistance film over the bottom electrode layer, wherein the variable resistance film comprises a first orthorhombic phase with a first fraction in the variable resistance film;
forming a top electrode layer over the variable resistance film; and
performing a laser anneal process to the substrate, the bottom electrode layer, the variable resistance film and the top electrode layer, wherein after performing the laser anneal process, the variable resistance film comprises a second orthorhombic phase with a second fraction in the variable resistance film, and the second fraction is different from the first fraction.

2. The method of claim 1, wherein the second fraction is higher than the first fraction.

3. The method of claim 1, wherein performing the laser anneal process comprises:
irradiating the top electrode layer using a laser beam having a pulse duration of about 1 nanoseconds to about 30 nanoseconds.

4. The method of claim 1, wherein performing the laser anneal process comprises:
irradiating the top electrode layer using a laser beam having a wavelength in a range from about 300 nm to about 400 nm.

5. The method of claim 1, wherein performing the laser anneal process comprises:
irradiating the top electrode layer using a laser beam having a wavelength in a range from about 1000 nm to about 1100 nm.

6. A method of forming a memory cell, comprising:
forming a bottom electrode layer over a substrate;
forming a variable resistance film over the bottom electrode layer, wherein the variable resistance film comprises a first tetragonal phase with a first fraction in the variable resistance film;
forming a top electrode layer over the variable resistance film; and
performing a laser anneal process to the bottom electrode layer, the variable resistance film and the top electrode layer, wherein after performing the laser anneal process, the variable resistance film comprises a second tetragonal phase with a second fraction in the variable resistance film, and the second fraction is different from the first fraction.

7. The method of claim 6, wherein the second fraction is lower than the first fraction.

8. The method of claim 6, wherein prior to performing the laser anneal process, the variable resistance film has an antiferroelectric phase.

9. The method of claim 6, wherein after performing the laser anneal process, the variable resistance film has a ferroelectric phase.

10. The method of claim 6, wherein after performing the laser anneal process, the variable resistance film has an orthorhombic phase with a third fraction in the variable resistance film, and the third fraction is higher than the first fraction.

11. The method of claim 6, wherein after performing the laser anneal process, the variable resistance film has an orthorhombic phase with a third fraction in the variable resistance film, and the third fraction is higher than the second fraction.

12. The method of claim 6, wherein performing the laser anneal process comprises:
irradiating the top electrode layer using a laser beam having a pulse duration of about 1 nanoseconds to about 30 nanoseconds.

13. The method of claim 12, wherein the laser beam is generated from a solid state laser source, a liquid state laser source, a gas state laser source or a semiconductor laser source.

14. The method of claim 12, wherein the laser beam is generated from a solid state laser source.

15. The method of claim 13, wherein the solid state laser source is Nd: YAG.

16. A memory cell, comprising:
a substrate;
a bottom electrode layer over the substrate;
a variable resistance film over the bottom electrode layer, wherein the variable resistance film comprises a plurality of phases comprising:
a tetragonal phase; and
an orthorhombic phase with a fraction in the variable resistance film greater than a fraction of the tetragonal phase in the variable resistance film; and
a top electrode layer over the variable resistance film.

17. The memory cell of claim 16, wherein the fraction of the orthorhombic phase in the variable resistance film is more than two times of the fraction of the tetragonal phase in the variable resistance film.

18. The memory cell of claim 16, wherein the variable resistance film further comprises:
a monoclinic phase with a fraction in the variable resistance film less than the fraction of the tetragonal phase in the variable resistance film.

19. The memory cell of claim 16, wherein the variable resistance film further comprises:
a monoclinic phase with a fraction in the variable resistance film less than the fraction of the orthorhombic phase in the variable resistance film.

20. The memory cell of claim 16, wherein the fraction of the orthorhombic phase in the variable resistance film is greater than 50% of total phases present in the variable resistance film.
